(19) United States
(12) Patent Application Publication
(10) Pub. No.: US 2024/0251594 A1
(43) Pub. Date: Jul. 25, 2024

(54) DISPLAY DEVICE AND MANUFACTURING METHOD THEREOF

(71) Applicant: Samsung Display Co., Ltd., Yongin-si (KR)

(72) Inventors: Beom-Soo SHIN, Yongin-si (KR); Suk Hoon KANG, Yongin-si (KR); Su Ji PARK, Yongin-si (KR); MINSEOK LEE, Yongin-si (KR); Sung Hwan HONG, Yongin-si (KR)

(21) Appl. No.: 18/515,496

(22) Filed: Nov. 21, 2023

(30) Foreign Application Priority Data
Jan. 25, 2023 (KR) 10-2023-0009632

(51) Int. Cl. H10K 50/86; H10K 50/854; H10K 59/38

(52) U.S. Cl. CPC H10K 50/865; H10K 50/854; H10K 59/38; H10K 59/122

(57) ABSTRACT

One or more embodiments of the present disclosure provide a color conversion panel including a substrate, a bank on the substrate, defining openings, and including a light-blocking area including black pigment on an upper portion thereof, a concentration of the black pigment increasing in a direction away from the substrate, and a color conversion layer and a transmission layer respectively in the openings.

### CROSS-REFERENCE TO RELATED APPLICATION

This application claims priority to, and the benefit of, Korean Patent Application No. 10-2023-0009632, filed in the Korean Intellectual Property Office on Jan. 25, 2023, the entire contents of which are incorporated herein by reference.

### BACKGROUND

### 1. Field

The present disclosure relates to a display device and a manufacturing method thereof.

### 2. Description of the Related Art

In a light-emitting device, a hole supplied from an anode and an electron supplied from a cathode are combined in a light-emitting layer formed between the anode and the cathode to form an exciton. The light-emitting device emits light while this exciton is stabilized.

The light-emitting device has several aspects, such as a wide viewing angle, a fast response speed, a thin thickness, and low power consumption, and thus it is widely applied to various electric and electronic devices, such as televisions, monitors, and mobile phones.

Recently, a display device including a color conversion panel has been proposed to implement a display device with high efficiency. The color conversion panel color-converts incident light into light having different colors, or transmits it.

The above information disclosed in this Background section is only for enhancement of understanding of the background of the present disclosure, and therefore, it may contain information that does not form the prior art that is already known in this country to a person of ordinary skill in the art.

### SUMMARY

Embodiments have been made in an effort to provide a display device and a manufacturing method thereof, which improves color reproducibility by increasing light efficiency and reducing or preventing color mixture.

One or more embodiments of the present disclosure provide a color conversion panel including a substrate, a bank on the substrate, defining openings, and including a light-blocking area including black pigment on an upper portion thereof, a concentration of the black pigment increasing in a direction away from the substrate, and a color conversion layer and a transmission layer respectively in the openings.

The black pigment may have hydrophobicity.

The black pigment may include fluorine-bonded carbon black or organic black.

A ratio of a thickness of the light-blocking area to a total thickness of the bank may be about 10% to about 20%.

A boundary of the light-blocking area in the bank may not be clearly defined.

The bank may include scatterers.

The scatterers may include one or more of SiO2, BaSO4, Al2O3, ZnO, ZrO2, or TiO2.

The color conversion panel may further include a color filter on the color conversion layer and the transmission layer.

The color conversion panel may further include a filler between the color conversion layer and the color filter, and between the transmission layer and the color filter.

One or more embodiments of the present disclosure provide a display device including a substrate, a transistor on the substrate, a light-emitting device connected to the transistor, an encapsulation layer on the light-emitting device, a bank on the encapsulation layer, defining openings, and including a light-blocking area including a black pigment on an upper portion thereof, a concentration of the black pigment increasing in a direction away from the substrate, and a color conversion layer and a transmission layer respectively in the openings of the bank.

The black pigment may have hydrophobicity.

The black pigment may include fluorine-bonded carbon black or organic black.

A ratio of a thickness of the light-blocking area to a total thickness of the bank may be about 10% to about 20%.

A boundary of the light-blocking area in the bank may not be clearly defined.

The bank may include scatterers.

The scatterers may include one or more of SiO2, BaSO4, Al2O3, ZnO, ZrO2, or TiO2.

The display device may further include a color filter on the color conversion layer and the transmission layer.

The display device may further include a filler between the color conversion layer and the color filter, and between the transmission layer and the color filter.

One or more embodiments of the present disclosure provide a manufacturing method of a display device, the method including coating a composition including scatterers and a black pigment having hydrophobicity on a substrate, heating the composition to induce phase separation of the black pigment, and forming a light-blocking area by exposing and developing the composition to fix the black pigment.

A concentration of the black pigment may increase in a direction away from the substrate.

According to the embodiments, it is possible to provide a display device, and a manufacturing method thereof, which improve color reproducibility by increasing light efficiency and reducing or preventing color mixture.

### BRIEF DESCRIPTION OF THE DRAWINGS

FIG. 1 schematically illustrates a display device according to one or more embodiments.

FIG. 2 illustrates an emission form of light in a display device according to one or more embodiments.

FIG. 3 illustrates that color mixing occurs when a bank does not include a light-blocking area.

FIG. 4 illustrates a configuration in which color mixing is reduced or prevented by a light-blocking area when the bank includes the light-blocking area.

FIG. 5 to FIG. 7 each illustrate a process of forming a bank according to one or more embodiments.

FIG. 8 illustrates reflectance and transmittance according to an amount of black pigment when black pigment is included in an entire bank.

FIG. 9 and FIG. 10 each illustrate a process of forming a light-blocking area as a separate additional process.

FIG. 11 illustrates a cross-section of a display device according to one or more other embodiments in more detail.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in different forms, and should not be construed as being limited to only the illustrated embodiments herein. Further, each of the features of the various embodiments of the present disclosure may be combined or combined with each other, in part or in whole, and technically various interlocking and driving are possible. Each embodiment may be implemented independently of each other or may be implemented together in an association. The described embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression such as “at least one of A and B” and “at least one of A or B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

The terminology used herein is for the purpose of describing particular embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

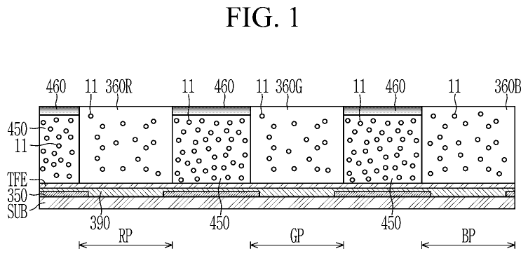

FIG. 1 schematically illustrates a display device according to one or more embodiments. Referring to FIG. 1, the display device may include a plurality of partition walls 350 and an emission layer 390 located on a substrate SUB. An encapsulation layer TFE may be located on the emission layer 390. In one or more embodiments, each emission layer 390 may be part of a light-emitting device connected to a transistor of each pixel. In FIG. 1, other portions are briefly illustrated for explanation of a bank 450, which is a key portion of the present disclosure, but the present disclosure is not limited thereto. An overall structure of the display device will be separately described in detail later.

The bank 450 including openings, and color conversion layers 360R and 360G and a transmission layer 360B positioned in the openings of the bank 450 are included on the encapsulation layer TFE. The color conversion layers 360R and 360G convert light incident on a color conversion panel to emit it. The red color conversion layer 360R may convert supplied blue light into red light. The green color conversion layer 360G may convert supplied blue light into green light. The red color conversion layer 360R and the green color conversion layer 360G may each include quantum dots.

In the present specification, the quantum dots indicate a crystal of a semiconductor compound, and may include any material capable of emitting light of various emission wavelengths according to a size of the crystal, or by adjusting a ratio of elements in the quantum dot compound.

A diameter of the quantum dots may be, for example, about 1 nm to about 10 nm.

The quantum dots may be synthesized by a wet chemical process, an organometallic chemical vapor deposition process, a molecular beam epitaxy process, or a process similar thereto.

The wet chemical process is a method of growing a quantum dot particle crystal after mixing an organic solvent and a precursor material. When the crystal grows, the organic solvent naturally acts as a dispersant coordinated on the surface of the quantum dot crystal, and controls the growth of the crystal. Accordingly, metal organic chemical vapor deposition (MOCVD) or molecular beam epitaxy (MBE) may be used, and the growth of quantum dot particles can be controlled through a process that is easier and cheaper than vapor deposition methods, such as epitaxy.

The quantum dots may include a Group III-VI semiconductor compound, a Group II-VI semiconductor compound, a Group III-V semiconductor compound, a Group III-VI semiconductor compound, a Group I-III-VI semiconductor compound, a Group IV-VI semiconductor compound, a Group IV elements or compound, or any combination thereof.

Examples of the Group II-VI semiconductor compound may include a two-element compound, such as CdS, CdSe, CdTe, ZnS, ZnSe, ZnTe, ZnO, HgS, HgSe, HgTe, MgSe, or MgS, a three-element compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, or MgZnS, and/or a four-element compound, such as HgZnTeS, CdZnSeS, CdZnSeTe, CdZnSTe, CdHgSeS, CdHgSeTe, CdHgSTe, HgZnSeS, HgZnSeTe, or HgZnSTe, or a combination thereof.

Examples of the Group III-V semiconductor compound may include a two-element compound, such as GaN, GaP, GaAs, GaSb, AlN, AlP, AlAs, AlSb, InN, InP, InAs, InSb, or the like, a three-element compound, such as GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP, or the like, and/or a four-element compound, such as GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or the like, or a combination thereof. Meanwhile, the Group III-V semiconductor compound may further include a Group II element. Examples of the Group III-V semiconductor compound further including the Group II element may include InZnP, InGaZnP, InAlZnP, or the like.

Examples of Group III-VI semiconductor compound may include a two-element compound, such as GaS, Ga₂S₃, GaSe, Ga₂Se₃, GaTe, InS, InSe, In₂Se₃, or InTe, a three-element compound, such as InGaS or InGaSe₃, or any combination thereof.

Examples of group I-III-VI semiconductor compound may include a three-element compound, such as AgInS, AgInS₂, AgInSe₂, AgGaS, AgGaS2, AgGaSe₂, CuInS, CuInS₂, CuInSe₂, CuGaS₂, CuGaSe₂, CuGaO₂, AgGaO₂, or AgAlO₂, a four-element compound, such as AgInGaS₂ or AgInGaSe₂, or any combination thereof.

Examples of the Group IV-VI semiconductor compound may include a two-element compound, such as SnS, SnSe, SnTe, PbS, PbSe, or PbTe, a three-element compound, such as SnSeS, SnSeTe, SnSTe, PbSeS, PbSeTe, PbSTe, SnPbS, SnPbSe, or SnPbTe, a fourth-element compound, such as SnPbSSe, SnPbSeTe, or SnPbSTe, or any combination thereof.

The Group IV element or compound may include a single-element compound, such as Si or Ge, a two-element compound, such as SiC or SiGe, or any combination thereof.

Each element included in a multi-element compound, such as a two-element compound, a three-element compound, and a four-element compound may be present in particles at a uniform concentration or a non-uniform concentration. That is, the chemical formula indicates types of elements included in the compound, and element ratios thereof in the compound may be different. For example, AgInGaS₂ may indicate AgInxGa1-xS2 (x being a real number between 0 and 1).

Meanwhile, the quantum dots may have a single structure in which a concentration of each element included in the quantum dots is uniform or in a dual core-shell structure. For example, a material included in the core and a material included in the shell may be different from each other.

The shell of the quantum dot may serve as a passivation layer for maintaining a semiconductor characteristic, and/or may serve as a charging layer for applying an electrophoretic characteristic to the quantum dot by reducing or preventing chemical denaturation of the core. The shell may be a single layer or a multilayer. An interface between the core and the shell may have a concentration gradient in which a concentration of elements of the shell decreases closer to a center thereof.

An example of the shell of the quantum dot includes a metal or nonmetal oxide, a semiconductor compound, or a combination thereof. Examples of oxides of metals or nonmetals may include two-element compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, a three-element compound, such as MgAl₂O₄, CoFe₂O₄, NiFe₂O₄, or CoMn₂O₄, or any combination thereof. Examples of the semiconductor compound may include a Group III-VI semiconductor compound, a Group II-VI semiconductor compound, a Group III-V semiconductor compound, a Group III-VI semiconductor compound, a Group I-III-VI semiconductor compound, a Group IV-VI semiconductor compound, or any combination thereof. Examples of the semiconductor compound may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AlP, AlSb, or any combination thereof.

Each element included in a multi-element compound, such as a two-element compound or a three-element compound may be present in particles at a uniform concentration or at a non-uniform concentration. That is, the chemical formula indicates types of elements included in the compound, and element ratios thereof in the compound may be different.

The quantum dots may have a full width at half maximum (FWHM) of the light-emitting wavelength spectrum that is equal to or less than about 45 nm, for example, equal to or less than about 40 nm, or equal to or less than about 30 nm, and in this range, color purity or color reproducibility may be improved. In addition, because light emitted through the quantum dot is emitted in all directions, a viewing angle of light may be improved.

In addition, a shape of the quantum dots may be in the form of spherical, pyramidal, multi-armed, or cubic nanoparticles, nanotubes, nanowires, nanofibers, nanoplatelet particles, or the like.

An energy band gap may be controlled by adjusting a size of the quantum dots or an element ratio in a quantum dot compound, and thus light of various wavelengths may be obtained from a quantum dot emission layer. Accordingly, a light-emitting device emitting light of various wavelengths may be implemented by using quantum dots as described above (using quantum dots of different sizes or having different element ratios in a quantum dot compound). For example, the size of the quantum dots may be controlled, or the element ratios in the quantum dot compound may be selected, to emit red, green and/or blue light. In addition, the quantum dots may be configured to emit white light by combining light of various colors.

Referring to FIG. 1, the display device may include a red pixel RP, a green pixel GP, and a blue pixel BP. The partition walls 350 and the banks 450 are positioned between each pixel area. The emission layer 390 is equally located in the entire pixel area, and may emit light of a single color (e.g., blue light). In the red pixel RP, incident blue light is color-converted to red in the red color conversion layer 360R to be emitted. In the red pixel GP, incident blue light is color-converted to green in the green color conversion layer 360G to be emitted. The blue light incident from the blue pixel BP is scattered and transmitted through the transmission layer 360B to be emitted. The transmission layer 360B may include scatterers 11. The scatterers may include one or more of SiO₂, BaSO₄, Al₂O₃, ZnO, ZrO₂, or TiO₂. The transmission layer 360B may each include a polymer resin and the scatterers 11 included in the polymer resin. For example, the transmission layer 360B may include TiO₂, but the present disclosure is not limited thereto.

The red color conversion layer 360R and the green color conversion layer 360G may also include the scatterers 11. Light that has been color-converted by the scatterers 11 is scattered to increase emission efficiency.

Referring to FIG. 1, the bank 450 is positioned between each of the color conversion layers 360R and 360G and the transmission layer 360B. The banks 450 may include scatterers. The scatterers may include one or more selected from a group including SiO₂, BaSO₄, Al₂O₃, ZnO, ZrO₂, or TiO₂.

As illustrated in FIG. 1, a light-blocking area 460 may be positioned at an upper portion of the bank 450. The light-blocking area 460 is an area including a black pigment. In this case, a boundary of a light-blocking area 460 in the bank 450 may not appear clearly. This is, because the light-blocking area 460 of the bank 450 is formed in a single process through phase separation, which will be described later, the bank 450 may have a concentration gradient in which a content of the black pigment gradually increases as a distance from the substrate SUB increases (e.g., toward an uppermost side of the bank 450). That is, the bank 450 may have a concentration gradient in which the content of the black pigment is highest at the uppermost side of the bank 450, and in which the content of the black pigment gradually decreases toward a bottom of the bank 450. The bank 450 and the light-blocking area 460 may be formed through phase separation of the black pigment having hydrophobicity, or being hydrophobic. In this case, the black pigment may have a form in which a fluorine group is bonded to carbon black or organic black. The fluorine group may include polytetrafluoroethylene or perfluoropolyether.

That is, the bank 450 may have the light-blocking area 460 positioned at an upper portion thereof, and may reduce or prevent color mixing between neighboring pixels.

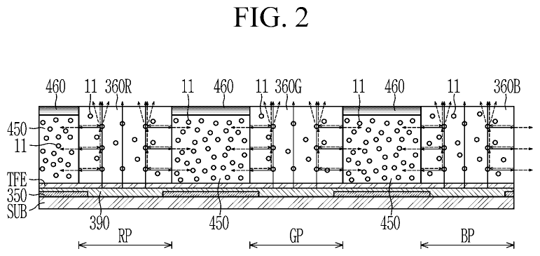

FIG. 2 illustrates an emission form of light in a display device according to one or more embodiments. Referring to FIG. 2, light emitted from each of the color conversion layers 360R and 360G, and from the transmission layer 360B, is emitted in various directions. In this case, the light emitted in the direction of the bank 450 is scattered by the scatterers of the bank 450 to be re-incident to the color conversion layer 360R, and to increase the emission efficiency. In addition, because each of the color conversion layers 360R and 360G also includes scatterers, light may be scattered.

The light-blocking area 460 positioned at an upper portion of the bank 450 to block reflection of external light. That is, light incident from the outside of the display device may be absorbed by the light-blocking area 460 positioned at the upper portion of the bank 450. As such, the bank 450 including the light-blocking area 460 may also reduce or prevent color mixing between neighboring pixels.

When the entire bank 450 includes a light-blocking material, light incident to the bank 450 may be absorbed, thereby decreasing light efficiency. In addition, when the entire bank 450 includes scatterers, color mixing between neighboring pixels may occur. However, because the bank 450 includes both the scattering area and the light-blocking area 460, it is possible to reduce or prevent color mixing of neighboring pixels while increasing light efficiency.

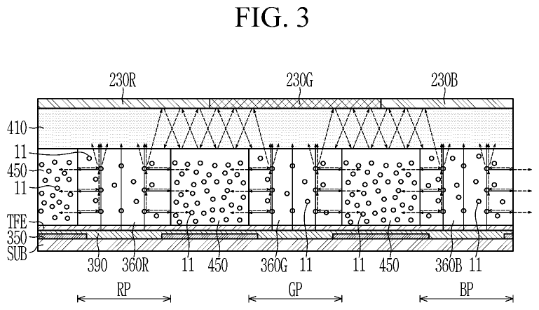

FIG. 3 illustrates that color mixing occurs when the bank 450 does not include a light-blocking area 460. Referring to FIG. 3, a red color filter 230R, a green color filter 230G, and a blue color filter 230B may be positioned in each pixel. As such, when the color conversion layers 360R, 360G and the transmission layer 360B overlap the color filters 230R, 230G, and 230B, the filler 410 may be positioned therebetween.

As illustrated in FIG. 3, when the bank 450 does not include the light-blocking area 460, color mixing may occur between the adjacent color conversion layers 360R and 360G and the transmission layer 360B. For example, as shown by arrows in FIG. 3, red light emitted from the red color conversion layer 360R may be incident to a green pixel area while being reflected from an area of a filler 410. This also may be the same between other pixels. However, the bank 450 may include the light-blocking area 460 in the display device, thereby reducing or preventing such color mixing issues.

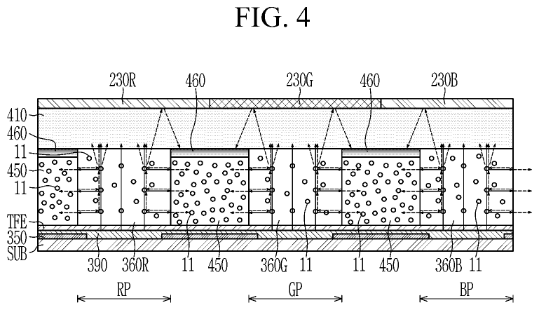

FIG. 4 illustrates a configuration in which color mixing is reduced or prevented by the light-blocking area 460 when the bank 450 includes the light-blocking area 460. As illustrated in FIG. 4, the light reflected from the area of the filler 410 is absorbed at the upper portion of the light-blocking area 460 of the bank 450, so the light is not incident to the adjacent pixel area, and so that no color mixing occurs.

As shown above, the bank 450 includes the light-blocking area 460, and the light-blocking area 460 has a concentration gradient. That is, as an uppermost layer of the bank 450 is approached, a content of the black pigment increases. This is because the light-blocking area 460 of the bank 450 is formed in a single process through phase separation.

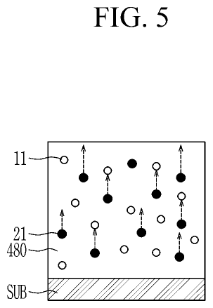

FIG. 5 to FIG. 7 each illustrate a process of forming the bank 450 according to one or more embodiments. Referring to FIG. 5, a bank composition 480 is coated on the substrate SUB. In this case, the scatterers 11 and black pigment 21 are evenly dispersed in the bank composition 480. In this case, the black pigment 21 has hydrophobicity, or includes a hydrophobic material, by bonding with a fluorine group. The black pigment may have a form in which a fluorine group is bonded to carbon black or organic black. The fluorine group may include polytetrafluoroethylene or perfluoropolyether.

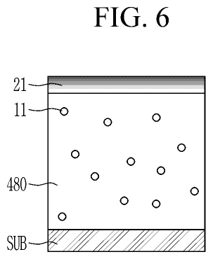

Referring to FIG. 6, the coated bank composition 480 is heated. By this heating, the black pigment 21 having hydrophobicity is phase-separated to an upper end of the bank.

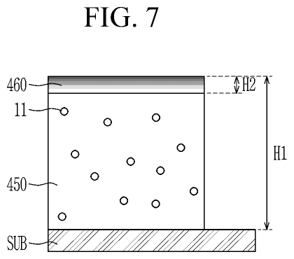

Next, referring to FIG. 7, the black pigment 21 having hydrophobicity is fixed to the upper end of the bank through exposure and development. In this case, a ratio of a thickness H2 of the light-blocking area 460 to a total thickness H1 of the bank 450 may be about 10% to about 20%. When a thickness of the light-blocking area is less than about 10%, a light-blocking effect may not be sufficient, and when the thickness of the light-blocking area is greater than about 20%, an amount of light absorbed may be large, resulting in deterioration in efficiency.

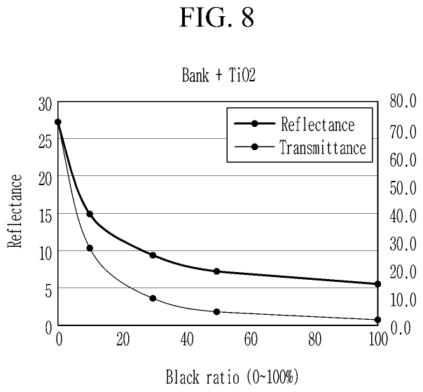

In general, when black pigment is added to the entire bank to improve reflectance, there is a problem in that reflectance and transmittance decrease. FIG. 8 illustrates reflectance and transmittance according to an amount of black pigment when black pigment is included in an entire bank. Referring to FIG. 8, it can be seen that the reflectance and transmittance is decreased as a content of the black pigment is increased.

However, in the case of the display device, the light-blocking area 460 is positioned only in an upper area of the bank 450 through phase separation. Accordingly, it is possible to increase light efficiency, and to reduce or prevent color mixing without reducing transmittance and reflectance.

In addition, because the bank 450 is manufactured in a single process through phase separation, it is economical because no additional process is required.

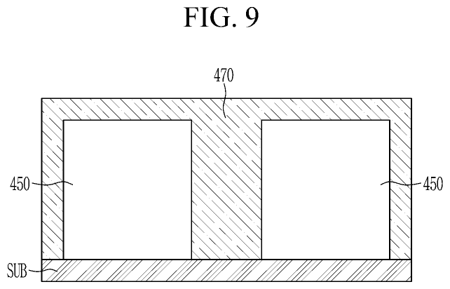

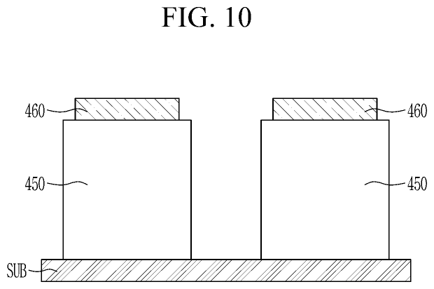

FIG. 9 and FIG. 10 each illustrate a process of forming a light-blocking area 460 as a separate additional process. Referring to FIG. 9, the bank 450 including scatterers is formed, and an entire area thereof is filled with a light-blocking material. Next, referring to FIG. 10, the light-blocking area 460 is formed by etching a light-blocking material. This requires a separate process, and considering alignment of the pattern when the light-blocking material is etched, a size of the light-blocking area 460 is inevitably smaller than that of the bank 450. Accordingly, light may not be blocked in some areas.

However, because the black pigment has hydrophobicity to form the light-blocking area 460 in one process through phase separation, the process is simple and economical. In the bank 450 manufactured in this way, the boundary of the light-blocking area 460 may not be clearly visible, and a content of the light-blocking material may increase toward an upper end of the bank 450.

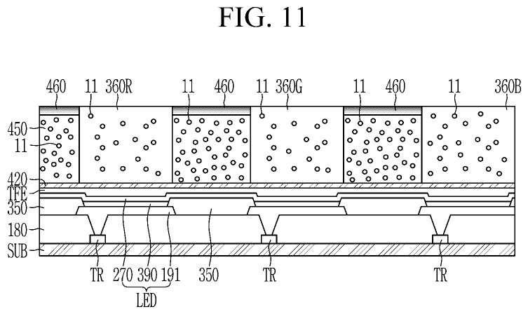

FIG. 11 illustrates a cross-section of a display device according to one or more other embodiments in more detail. Referring to FIG. 11, a substrate SUB, a plurality of transistors TR positioned on the substrate SUB, and an insulating layer 180 are included. A first electrode 191 and a partition wall 350 are positioned on the insulating layer 180, and the first electrode 191 is connected to the transistors TR. In one or more embodiments, the transistor TR may include a semiconductor layer, source and drain electrodes connected to the semiconductor layer, and a gate electrode insulated from the semiconductor layer. A second electrode 270 is positioned on the partition wall 350, and the emission layer 390 is positioned between the first electrode 191 and the second electrode 270. The first electrode 191, the second electrode 270, and the emission layer 390 are collectively referred to as a light-emitting device LED. The light-emitting devices LED may emit light of different colors, or may emit light of a same color. For example, the light-emitting devices LED may emit light of red, green, and blue. Alternatively, the light-emitting devices LED may emit blue light and green light. The light-emitting devices LED may have structures in which light-emitting devices emitting different respective colors are stacked. For example, in the light-emitting devices LED, a light-emitting layer for emitting blue light and a light-emitting layer for emitting green light may be stacked. Alternatively, light-emitting layers for emitting blue light, green light, and red light may be stacked.

In FIG. 11, an encapsulation layer TFE may be positioned on the light-emitting device LED. The encapsulation layer TFE may have a multi-layered structure in which an organic layer and an inorganic layer are alternately stacked. Among multi-layered encapsulation layers (TFE) a layer that is positioned farthest from the substrate SUB may include SiON.

A buffer layer 420 may be located on the encapsulation layer TFE. The buffer layer 420 may couple the display panel and the color conversion panel to each other. The buffer layer 420 may include an organic material. A refractive index of the buffer layer may be in a range of about 1.6 to about 1.7. This refractive index is in a range of the refractive index in which an extraction efficiency of light emitted from the display panel is the best. According to one or more embodiments, the buffer layer 420 may be omitted.

Next, a plurality of banks 450 are positioned on the buffer layer 420. The banks 450 each include a light-blocking area 460. Descriptions of the banks 450 and the light-blocking area 460 are the same as those described above, and thus are omitted. The color conversion layers 360R and 360G and the transmission layer 360B are positioned between the banks 450. Descriptions of the color conversion layers 360R and 360G and the transmission layer 360B are omitted because they are the same as described above.

That is, in the display device, the banks 450 each include scatterers and a black pigment, and the black pigment constitutes the light-blocking area 460 at upper sides of the banks 450. Because the banks 450 and the light-blocking area 460 can be formed in a single process, the process may be more economical, and color mixing can be reduced or prevented without impairing the transmittance of the display device.

While the present disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims, with functional equivalents thereof to be included therein.

What is claimed is:

1. A color conversion panel comprising:
a substrate;
a bank on the substrate, defining openings, and comprising a light-blocking area comprising black pigment on an upper portion thereof, a concentration of the black pigment increasing in a direction away from the substrate; and
a color conversion layer and a transmission layer respectively in the openings.

2. The color conversion panel of claim 1, wherein the black pigment has hydrophobicity.

3. The color conversion panel of claim 1, wherein the black pigment comprises fluorine-bonded carbon black or organic black.

4. The color conversion panel of claim 1, wherein a ratio of a thickness of the light-blocking area to a total thickness of the bank is about 10% to about 20%.

5. The color conversion panel of claim 1, wherein a boundary of the light-blocking area in the bank is not clearly defined.

6. The color conversion panel of claim 1, wherein the bank comprises scatterers.

7. The color conversion panel of claim 6, wherein the scatterers comprise one or more of SiO₂, BaSO₄, Al₂O₃, ZnO, ZrO₂, or TiO₂.

8. The color conversion panel of claim 1, further comprising a color filter on the color conversion layer and the transmission layer.

9. The color conversion panel of claim 8, further comprising a filler between the color conversion layer and the color filter, and between the transmission layer and the color filter.

10. A display device comprising:
a substrate;
a transistor on the substrate;
a light-emitting device connected to the transistor;
an encapsulation layer on the light-emitting device;
a bank on the encapsulation layer, defining openings, and comprising a light-blocking area comprising a black pigment on an upper portion thereof, a concentration of the black pigment increasing in a direction away from the substrate; and
a color conversion layer and a transmission layer respectively in the openings of the bank.

11. The display device of claim 10, wherein the black pigment has hydrophobicity.

12. The display device of claim 10, wherein the black pigment comprises fluorine-bonded carbon black or organic black.

13. The display device of claim 10, wherein a ratio of a thickness of the light-blocking area to a total thickness of the bank is about 10% to about 20%.

14. The display device of claim 10, wherein a boundary of the light-blocking area in the bank is not clearly defined.

15. The display device of claim 10, wherein the bank comprises scatterers.

16. The display device of claim 15, wherein the scatterers comprise one or more of SiO₂, BaSO₄, Al₂O₃, ZnO, ZrO₂, or TiO₂.

17. The display device of claim 10, further comprising a color filter on the color conversion layer and the transmission layer.

18. The display device of claim 17, further comprising a filler between the color conversion layer and the color filter, and between the transmission layer and the color filter.

19. A manufacturing method of a display device, the method comprising:
coating a composition comprising scatterers and a black pigment having hydrophobicity on a substrate;
heating the composition to induce phase separation of the black pigment; and
forming a light-blocking area by exposing and developing the composition to fix the black pigment.

20. The manufacturing method of claim 19, wherein a concentration of the black pigment increases in a direction away from the substrate.
